(19) United States
(12) Patent Application Publication
(10) Pub. No.: US 2025/0253807 A1
(43) Pub. Date: Aug. 7, 2025

(54) POWER AMPLIFYING CIRCUIT

(71) Applicant: Murata Manufacturing Co., Ltd., Kyoto (JP)

(72) Inventor: Kenichi SHIMAMOTO, Kyoto (JP)

(21) Appl. No.: 19/043,012

(22) Filed: Jan. 31, 2025

(30) Foreign Application Priority Data
Feb. 1, 2024 (JP) 2024-014107

(51) Int. Cl. H03F 1/02; H03F 1/10

(52) U.S. Cl. CPC H03F 1/0233; H03F 1/10; H03F 2200/465

(57) ABSTRACT

A power amplifying circuit includes: a first amplifier that includes a field effect transistor as an amplifying element, amplifies a first radio frequency signal, and outputs a second radio frequency signal; a second amplifier that includes a bipolar transistor as an amplifying element, amplifies the second radio frequency signal, and outputs a third radio frequency signal; a control part that outputs a control signal, the control signal controlling a first power supply voltage to be supplied to the first amplifier; and a regulator that outputs the first power supply voltage to the first amplifier, the first power supply voltage being a voltage that depends on the control signal. A second power supply voltage to be supplied to the second amplifier is an envelope tracking voltage.

### CROSS REFERENCE TO RELATED APPLICATION

This application claims priority from Japanese Patent Application No. 2024-014107 filed on Feb. 1, 2024. The content of this application is incorporated herein by reference in its entirety.

### BACKGROUND

The present disclosure relates to power amplifying circuits.

Japanese Unexamined Patent Application Publication No. 5-152978 describes a radio frequency power amplifying circuit that uses a silicon MOS FET power amplifying element in a front stage and a GaAs FET power amplifying element in a subsequent stage.

Such a power amplifying circuit in which a plurality of amplifiers, each being formed on a different semiconductor material substrate, are combined is known in the art.

Further, in some cases, an amplifier that includes a Field Effect Transistor (FET) formed on a silicon (for example, SOI (Silicon On Insulator)) substrate is referred to as an FET amplifier. Note that examples of the silicon substrate include a SOI-CMOS structure, a Bulk-CMOS structure, a SOS-CMOS structure, and the like. However, the present disclosure is not limited to these examples.

Further, in some cases, an amplifier that includes a bipolar transistor formed on a gallium arsenide (GaAs) substrate is referred to as a bipolar amplifier.

### BRIEF SUMMARY

While FETs have suitable radio frequency characteristics, FETs also have characteristics such that breakdown voltages between terminals (drain-to-source breakdown voltage and gate-to-source breakdown voltage) are low.

For example, the drain-to-source breakdown voltage of FETs is lower than the collector-to-emitter breakdown voltage of bipolar transistors. In many cases, values of the gate-to-source breakdown voltages of FETs are detected to be lower than the base-to-emitter breakdown voltages.

Because of this, a typical FET amplifier uses a fixed power supply voltage or APT (Average Power Tracking) for power supply voltage. This allows for easy control of the voltage between FET terminals to be equal to or below the breakdown voltage between terminals.

As a technique for improving power efficiency by suppressing amplifier's loss, an envelope tracking technique is known in the art. The envelope tracking technique is a technique that varies the power supply voltage of an amplifier in a manner that depends on an envelope curve of a radio frequency signal.

In view of power efficiency, even in the power amplifying circuit in which a plurality of amplifiers, each being formed on a different semiconductor material substrate, are combined, it is desirable to apply the envelope tracking technique to both the FET amplifier and the bipolar amplifier. However, applying the envelope tracking technique on the FET amplifier is difficult, as stated below.

When an amplifier is used in a cellular communication device (for example, a smartphone, a tablet, or the like), the power supply voltage of the amplifier varies across a wide range. Further, in the envelope tracking technique, the band at which the power supply voltage varies can be equal to or higher than 100 MHz (megahertz). Accordingly, for FETs, in the case where the bias voltage (gate voltage) cannot be varied to follow the power supply voltage at a band of 100 MHz or higher, the voltage between terminals may exceed the breakdown voltage between terminals, and this may cause damage to the FET.

The present disclosure balances the improvement of efficiency of a power amplifying circuit and the damage suppression.

A power amplifying circuit according to one aspect of the present disclosure includes: a first amplifier that includes a field effect transistor as an amplifying element, amplifies a first radio frequency signal, and outputs a second radio frequency signal; a second amplifier that includes a bipolar transistor as an amplifying element, amplifies the second radio frequency signal, and outputs a third radio frequency signal; a control part that outputs a control signal, the control signal controlling a first power supply voltage to be supplied to the first amplifier; and a regulator that outputs the first power supply voltage to the first amplifier, the first power supply voltage being a voltage that depends on the control signal. A second power supply voltage to be supplied to the second amplifier is an envelope tracking voltage.

According to the present disclosure, it becomes possible to balance the improvement of efficiency of a power amplifying circuit and the damage suppression.

### BRIEF DESCRIPTION OF THE DRAWINGS

FIG. 1 is a diagram illustrating a configuration of a power amplifying circuit according to a first embodiment;

FIG. 2 is a diagram illustrating one example of a table stored in a memory part;

FIG. 3 is a diagram illustrating one example of a configuration of a variable resistor;

FIG. 4 is a diagram illustrating a circuit simulation result of a power amplifying circuit of a comparative example;

FIG. 5 is a diagram illustrating a circuit simulation result of a power amplifying circuit of the first embodiment;

FIG. 6 is a diagram illustrating a circuit simulation result of the power amplifying circuit of the first embodiment;

FIG. 7 is a diagram illustrating a circuit simulation result of the power amplifying circuit of the first embodiment;

FIG. 8 is a diagram illustrating a circuit simulation result of the power amplifying circuit of the first embodiment;

FIG. 9 is a diagram illustrating a configuration of a power amplifying circuit according to a second embodiment;

FIG. 10 is a diagram illustrating one example of a detection characteristic of a power detector;

FIG. 11 is a diagram illustrating a configuration of a power amplifying circuit according to a third embodiment;

FIG. 12 is a diagram illustrating a configuration of a power amplifying circuit according to a fourth embodiment;

FIG. 13 is a diagram illustrating a configuration of a power amplifying circuit according to a fifth embodiment;

FIG. 14 is a diagram illustrating a configuration of a power amplifying circuit according to a sixth embodiment; and

FIG. 15 is a diagram illustrating an example modification of the power amplifying circuit according to the fourth embodiment.

### DETAILED DESCRIPTION

Hereinafter, embodiments of the present disclosure will be described in detail on the basis of the drawings. Note that the present disclosure is not limited by these embodiments. Needless to say, each embodiment is for illustrative purposes only, and constituent elements illustrated in different embodiments may be combined or partially exchanged. In the description of the second embodiment and subsequent embodiments, descriptions regarding matters common to the first embodiment will not be repeated, and only points different from the first embodiment will be described. Particularly, similar actions and effects produced by similar constituent elements will not be repeated in each embodiment.

### First Embodiment

### Configuration

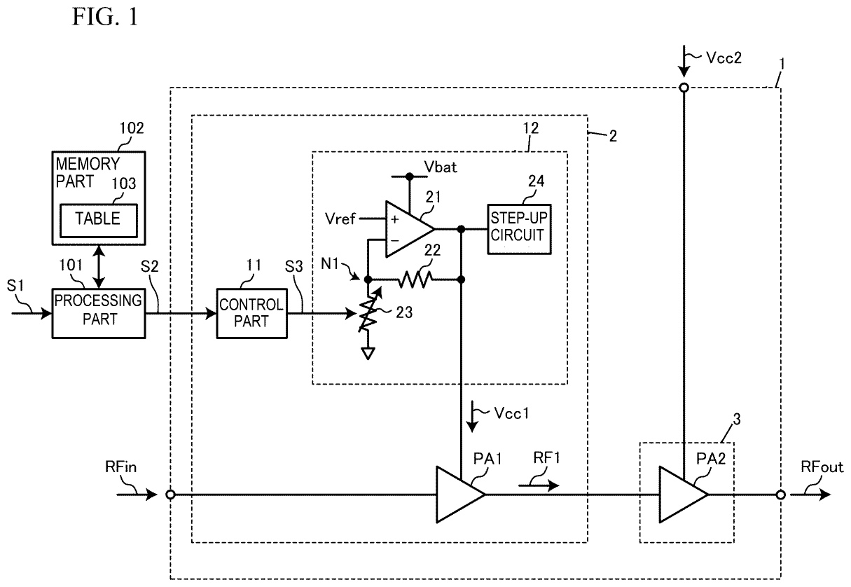

FIG. 1 is a diagram illustrating a configuration of a power amplifying circuit according to the first embodiment.

A power amplifying circuit 1 amplifies a radio frequency signal RFin and outputs a radio frequency signal RFout. In one example, the power amplifying circuit 1 is installed in a cellular communication device (for example, a smartphone, a tablet, or the like). However, the present disclosure is not limited thereto.

On the basis of a signal S1 output from a control part of the cellular communication device, a processing part 101 looks up a table 103 stored in a memory part 102 and outputs a signal S2 to the power amplifying circuit 1. On the basis of the signal S2, the power amplifying circuit 1 controls a first power supply voltage Vcc1 (to be described later) of a first amplifier PA1 (to be described later).

On the basis of power of the cellular communication device (for example, a power mode of the cellular communication device, output power Pout, or the like), the control part of the cellular communication device outputs the signal S1. That is to say, the signal S1 is a signal that represents the power. In one example, the power mode of the cellular communication device is, for example, High Power Mode (HPM) or Low Power Mode (LPM). However, the present disclosure is not limited thereto.

In one example, the High Power Mode is an amplifying operation of the cellular communication device with a first output power that is relatively high, and the Low Power Mode is an amplifying operation of the cellular communication device with a second output power that is relatively low. However, the present disclosure is not limited thereto.

In one example, the memory part 102 is a ROM (Read Only Memory), a RAM (Random Access Memory), a flash memory (registered trademark), or the like. However, the present disclosure is not limited thereto.

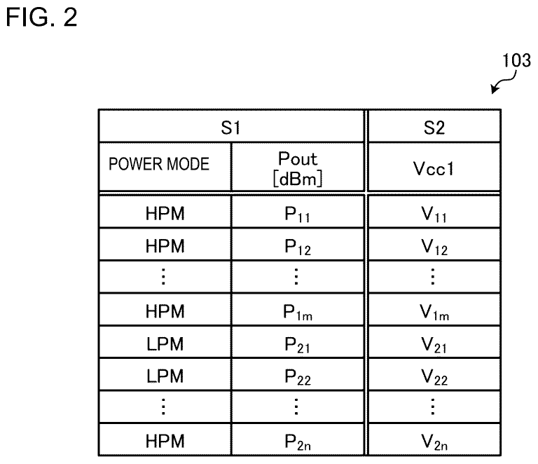

FIG. 2 is a diagram illustrating one example of a table stored in the memory part.

A table 103 links information of the signal S1 with information of the signal S2. In one example, the information of the signal S1 includes information about the power mode of the cellular communication device (for example, HPM and LPM) and information about the output power Pout [dBm]. However, the present disclosure is not limited thereto. In one example, the information of the signal S2 includes information about the first power supply voltage Vcc1. However, the present disclosure is not limited thereto.

For example, in the High Power Mode, V₁₁≥V₁₂≥ . . . ≥V₁ₘ in one example, in the case where P₁₁>P₁₂> . . . >P₁ₘ. That is to say, in one example, in the High Power Mode, the first power supply voltage Vcc1 increases as the output power Pout increases, while the first power supply voltage Vcc1 decreases as the output power Pout decreases. However, the present disclosure is not limited thereto.

Further, for example, in the Low Power Mode, V₂₁≥V₂₂≥ . . . ≥V₂ₙ in one example, in the case where P₂₁>P₂₂> . . . >P₂ₙ. That is to say, in one example, in the Low Power Mode, the first power supply voltage Vcc1 increases as the output power Pout increases, while the first power supply voltage Vcc1 decreases as the output power Pout decreases. However, the present disclosure is not limited thereto.

On the basis of the signal S1, the processing part 101 looks up the table 103, determines the signal S2, and outputs the signal S2 to the power amplifying circuit 1.

Referring to FIG. 1 again, the power amplifying circuit 1 includes a first semiconductor substrate 2 and a second semiconductor substrate 3. The first semiconductor substrate 2 is a silicon (for example, SOI (Silicon On Insulator)) substrate. The second semiconductor substrate 3 is a gallium arsenide (GaAs) substrate.

A control part 11, a regulator 12, and the first amplifier PA1 are formed on the first semiconductor substrate 2. The first amplifier PA1 includes a Field Effect Transistor (FET). The first amplifier PA1 may alternatively be formed by stacking a plurality of FETs (drain-to-source paths are connected in series).

A second amplifier PA2 is formed on the second semiconductor substrate 3. The second amplifier PA2 includes a bipolar transistor.

An input terminal of the second amplifier PA2 is electrically connected to an output terminal of the first amplifier PA1.

Each transistor may alternatively be a multi-finger transistor in which a plurality of unit transistors are electrically connected in parallel to each other. The unit transistor corresponds to a minimum configuration that forms a transistor.

On the basis of the signal S2 output from the processing part 101, the control part 11 outputs a signal S3 to a switch 41 (to be described later) included in a variable resistor 23 included in the regulator 12 to control the resistance value of the variable resistor 23. This allows the control part 11 to control the first power supply voltage Vcc1. In one example, the control part 11 communicates with the processing part 101 using MIPI (Mobile Industry Processor Interface). However, the present disclosure is not limited thereto.

The regulator 12 outputs the first power supply voltage Vcc1, which is a voltage based on the signal S3 input from the control part 11, to the first amplifier PA1. The regulator 12 is capable of varying the first power supply voltage Vcc1 on the basis of the signal S3. For example, on the basis of the signal S3, the regulator 12 is capable of outputting a constant voltage of 2V as the first power supply voltage Vcc1, outputting a constant voltage of 3V as the first power supply voltage Vcc1, outputting a constant voltage of 4V as the first power supply voltage Vcc1, or outputting a constant voltage of 5V as the first power supply voltage Vcc1.

Note that the first power supply voltage Vcc1 may alternatively be a constant voltage that provides a constant output in a manner that depends on the signal.

The regulator 12 includes an operational amplifier 21, a resistor 22, the variable resistor 23, and a step-up circuit 24.

The operational amplifier 21 operates using a power supply voltage Vbat. A reference voltage Vref is input to a non-inverting input terminal (+terminal) of the operational amplifier 21. An inverting input terminal (−terminal) of the operational amplifier 21 is electrically connected to a node N1.

One end portion of the resistor 22 is electrically connected to an output terminal of the operational amplifier 21. The other end portion of the resistor 22 is electrically connected to the node N1.

That is to say, a negative feedback is applied to the operational amplifier 21.

One end portion of the variable resistor 23 is electrically connected to the node N1. The other end portion of the variable resistor 23 is electrically connected to a reference potential. In one example, the reference potential is a ground potential. However, the present disclosure is not limited thereto.

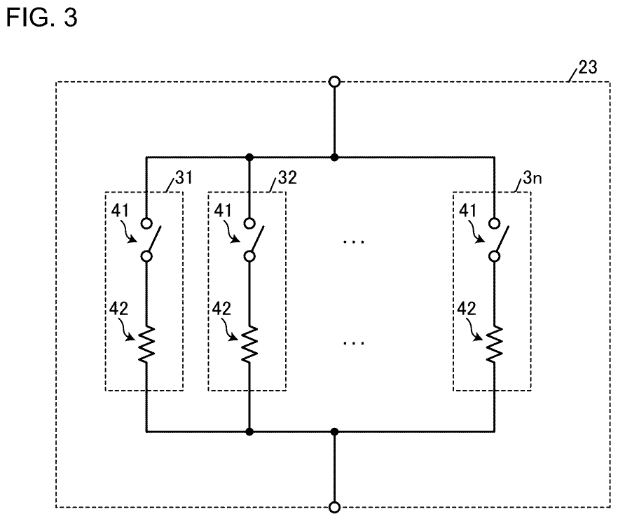

FIG. 3 is a diagram illustrating one example of the configuration of the variable resistor.

The variable resistor 23 includes circuits 31, 32, . . . , and 3n. The circuits 31, 32, . . . , and 3n are connected in parallel to each other.

In each of the circuits 31, 32, . . . , and 3n, a switch 41 and a resistor 42 are connected in series.

When the control part 11 turns the switches 41 included in the circuits 31, 32, . . . , and 3n on or off, the number of the resistors 42 connected in parallel to each other changes, and this enables the resistance value of the variable resistor 23 to vary. The resistance value of the variable resistor 23 increases as the number of the resistors 42 connected in parallel to each other decreases, while the resistance value of the variable resistor 23 decreases as the number of the resistors 42 connected in parallel to each other increases.

Referring to FIG. 1 again, the voltage of the node N1 is obtained by dividing the first power supply voltage Vcc1 by the resistor 22 and the variable resistor 23. The voltage of the node N1 decreases as the resistance value of the variable resistor 23 decreases, while the voltage of the node N1 increases as the resistance value of the variable resistor 23 increases.

The operational amplifier 21 outputs the first power supply voltage Vcc1 that depends on the resistance value of the variable resistor 23. More specifically, the operational amplifier 21 increases the first power supply voltage Vcc1 when the resistance value of the variable resistor 23 decreases (the voltage of the node N1 decreases). Further, the operational amplifier 21 decreases the first power supply voltage Vcc1 when the resistance value of the variable resistor 23 increases (the voltage of the node N1 increases).

The control part 11 controls the resistance value of the variable resistor 23 in such a way that the resistance value of the variable resistor 23 decreases as the power increases, and as the power increases, the regulator 12 increases the first power supply voltage Vcc1.

The control part 11 controls the resistance value of the variable resistor 23 in such a way that the resistance value of the variable resistor 23 increases as the power decreases, and as the power decreases, the regulator 12 decreases the first power supply voltage Vcc1.

The step-up circuit 24 is electrically connected to the output terminal of the operational amplifier 21. The step-up circuit 24 does not operate when the first power supply voltage Vcc1 output from the operational amplifier 21 is sufficient. In a case where a voltage higher than the first power supply voltage Vcc1 output from the operational amplifier 21 is required, the step-up circuit 24 increases the first power supply voltage Vcc1. In a case where the first power supply voltage Vcc1 output from the operational amplifier 21 is sufficient, the step-up circuit 24 can be omitted.

The first amplifier PA1 operates using the first power supply voltage Vcc1. The first amplifier PA1 amplifies the radio frequency signal RFin and outputs a radio frequency signal RF1 to the second amplifier PA2.

The second amplifier PA2 operates using a second power supply voltage Vcc2. The second power supply voltage Vcc2 is, for example, an envelope tracking voltage that varies in a manner that depends on an envelope curve of the radio frequency signal RFin or the radio frequency signal RFout using the envelope tracking technique. The second amplifier PA2 amplifies the radio frequency signal RF1 and outputs the radio frequency signal RFout.

### Circuit Simulation Result of Comparative Example

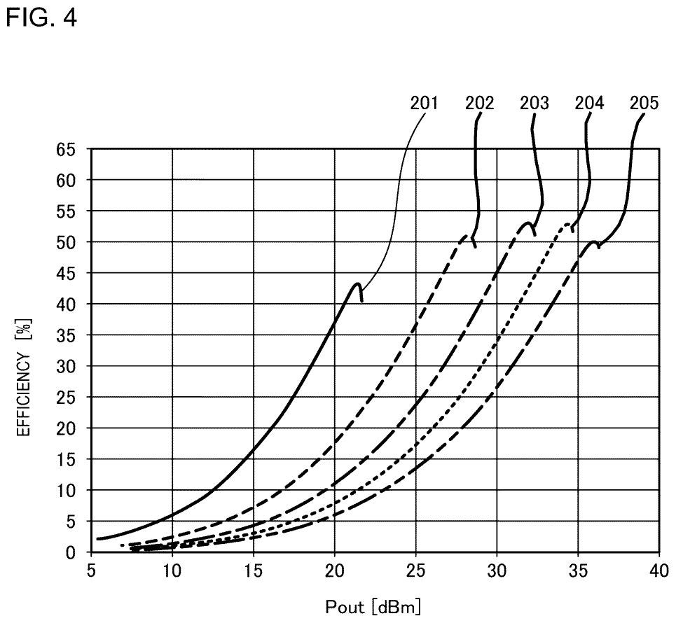

FIG. 4 is a diagram illustrating a circuit simulation result of a power amplifying circuit of a comparative example. FIG. 4 is a diagram illustrating a circuit simulation result of the power amplifying circuit 1 when an envelope tracking technique is applied to both the first power supply voltage Vcc1 and the second power supply voltage Vcc2. In FIG. 4, the horizontal axis represents the output power Pout [dBm], and the vertical axis represents the efficiency [%].

In FIG. 4, a curve 201 indicates the relationship between the output power Pout and the efficiency of the power amplifying circuit 1 when the second power supply voltage Vcc2 is 1 V. A curve 202 indicates the relationship between the output power Pout and the efficiency of the power amplifying circuit 1 when the second power supply voltage Vcc2 is 2 V. A curve 203 indicates the relationship between the output power Pout and the efficiency of the power amplifying circuit 1 when the second power supply voltage Vcc2 is 3 V. A curve 204 indicates the relationship between the output power Pout and the efficiency of the power amplifying circuit 1 when the second power supply voltage Vcc2 is 4 V. A curve 205 indicates the relationship between the output power Pout and the efficiency of the power amplifying circuit 1 when the second power supply voltage Vcc2 is 5 V.

### Circuit Simulation Result of First Embodiment

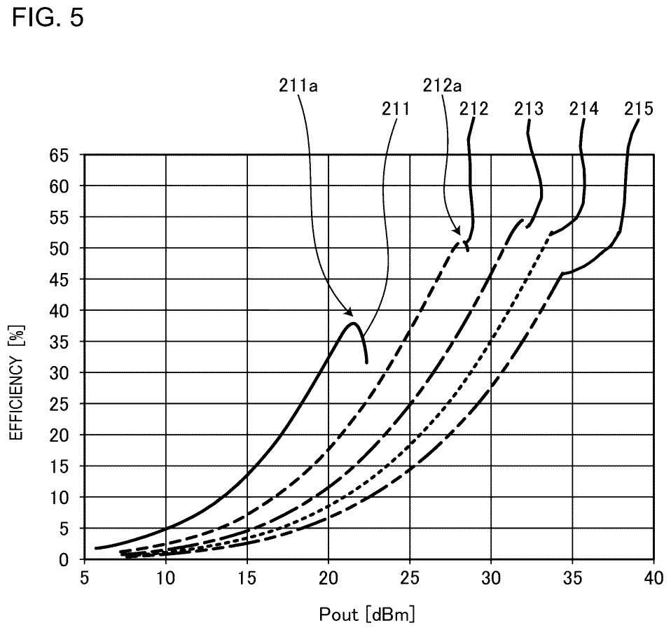

FIG. 5 to FIG. 8 are diagrams each illustrating a circuit simulation result of a power amplifying circuit of the first embodiment. In FIG. 5 to FIG. 8, the horizontal axis represents the output power Pout [dBm], and the vertical axis represents the efficiency [%].

FIG. 5 is a diagram illustrating a circuit simulation result of the power amplifying circuit 1 when the first power supply voltage Vcc1 is 2 V.

In FIG. 5, a curve 211 indicates the relationship between the output power Pout and the efficiency of the power amplifying circuit 1 when the second power supply voltage Vcc2 is 1 V. A curve 212 indicates the relationship between the output power Pout and the efficiency of the power amplifying circuit 1 when the second power supply voltage Vcc2 is 2 V. A curve 213 indicates the relationship between the output power Pout and the efficiency of the power amplifying circuit 1 when the second power supply voltage Vcc2 is 3 V. A curve 214 indicates the relationship between the output power Pout and the efficiency of the power amplifying circuit 1 when the second power supply voltage Vcc2 is 4 V. A curve 215 indicates the relationship between the output power Pout and the efficiency of the power amplifying circuit 1 when the second power supply voltage Vcc2 is 5 V.

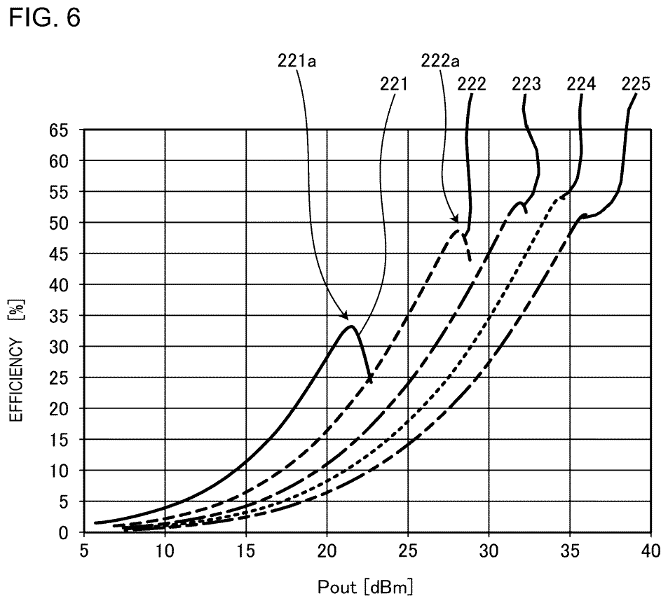

FIG. 6 is a diagram illustrating a circuit simulation result of the power amplifying circuit 1 when the first power supply voltage Vcc1 is 3 V.

In FIG. 6, a curve 221 indicates the relationship between the output power Pout and the efficiency of the power amplifying circuit 1 when the second power supply voltage Vcc2 is 1 V. A curve 222 indicates the relationship between the output power Pout and the efficiency of the power amplifying circuit 1 when the second power supply voltage Vcc2 is 2 V. A curve 223 indicates the relationship between the output power Pout and the efficiency of the power amplifying circuit 1 when the second power supply voltage Vcc2 is 3 V. A curve 224 indicates the relationship between the output power Pout and the efficiency of the power amplifying circuit 1 when the second power supply voltage Vcc2 is 4 V. A curve 225 indicates the relationship between the output power Pout and the efficiency of the power amplifying circuit 1 when the second power supply voltage Vcc2 is 5 V.

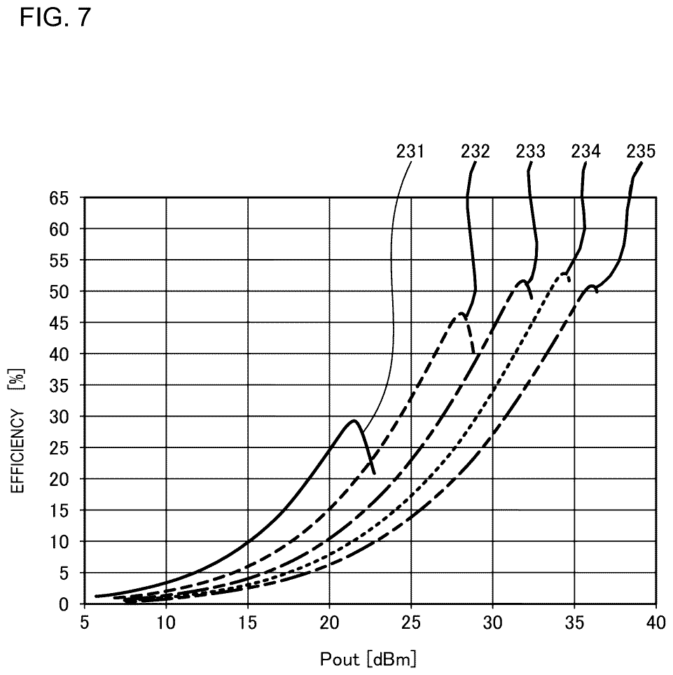

FIG. 7 is a diagram illustrating a circuit simulation result of the power amplifying circuit 1 when the first power supply voltage Vcc1 is 4 V.

In FIG. 7, a curve 231 indicates the relationship between the output power Pout and the efficiency of the power amplifying circuit 1 when the second power supply voltage Vcc2 is 1 V. A curve 232 indicates the relationship between the output power Pout and the efficiency of the power amplifying circuit 1 when the second power supply voltage Vcc2 is 2 V. A curve 233 indicates the relationship between the output power Pout and the efficiency of the power amplifying circuit 1 when the second power supply voltage Vcc2 is 3 V. A curve 234 indicates the relationship between the output power Pout and the efficiency of the power amplifying circuit 1 when the second power supply voltage Vcc2 is 4 V. A curve 235 indicates the relationship between the output power Pout and the efficiency of the power amplifying circuit 1 when the second power supply voltage Vcc2 is 5 V.

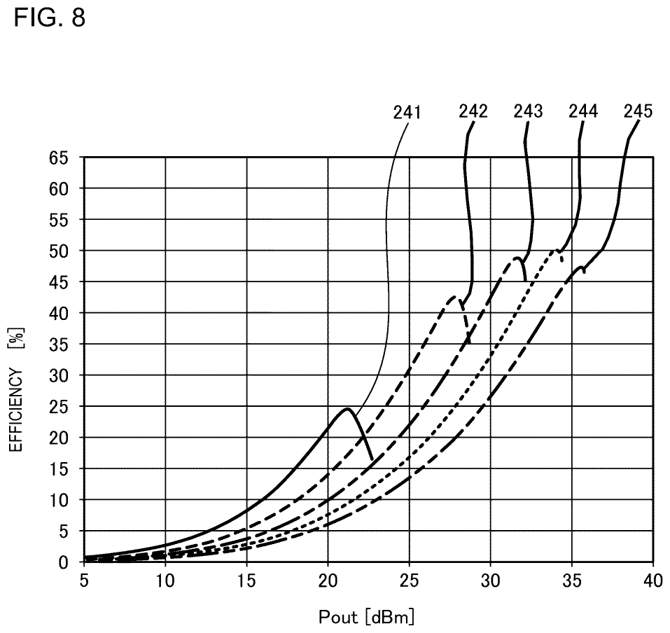

FIG. 8 is a diagram illustrating a circuit simulation result of the power amplifying circuit 1 when the first power supply voltage Vcc1 is 5 V.

In FIG. 8, a curve 241 indicates the relationship between the output power Pout and the efficiency of the power amplifying circuit 1 when the second power supply voltage Vcc2 is 1 V. A curve 242 indicates the relationship between the output power Pout and the efficiency of the power amplifying circuit 1 when the second power supply voltage Vcc2 is 2 V. A curve 243 indicates the relationship between the output power Pout and the efficiency of the power amplifying circuit 1 when the second power supply voltage Vcc2 is 3 V. A curve 244 indicates the relationship between the output power Pout and the efficiency of the power amplifying circuit 1 when the second power supply voltage Vcc2 is 4 V. A curve 245 indicates the relationship between the output power Pout and the efficiency of the power amplifying circuit 1 when the second power supply voltage Vcc2 is 5 V.

### Effects

For example, the attention is focused on a local maximum point 211a in the curve 211 (where the second power supply voltage Vcc2 is 1 V) of FIG. 5 (where the first power supply voltage Vcc1 is 2 V) and a local maximum point 221a in the curve 221 (where the second power supply voltage Vcc2 is 1 V) of FIG. 6 (where the first power supply voltage Vcc1 is 3 V).

The output power Pout at the local maximum point 211a is approximately 21.5 dBm, and the efficiency at the local maximum point 211a is approximately 38%. The output power Pout at the local maximum point 221a is approximately 21.5 dBm, and the efficiency at the local maximum point 221a is approximately 33%.

As described above, when the second power supply voltage Vcc2 is low (in this example, the second power supply voltage Vcc2 is 1 V), that is, when the power is low, the efficiency is higher when the first power supply voltage Vcc1 is lower (in this example, the first power supply voltage Vcc1 is 1 V).

Further, for example, the attention is focused on a local maximum point 212a in the curve 212 (where the second power supply voltage Vcc2 is 2 V) of FIG. 5 (where the first power supply voltage Vcc1 is 2 V) and a local maximum point 222a in the curve 222 (where the second power supply voltage Vcc2 is 2 V) of FIG. 6 (where the first power supply voltage Vcc1 is 3 V).

The output power Pout at the local maximum point 212a is approximately 28 dBm, and the efficiency at the local maximum point 212a is approximately 51%. The output power Pout at the local maximum point 222a is approximately 28 dBm, and the efficiency at the local maximum point 222a is approximately 48%.

As described above, when the second power supply voltage Vcc2 is low (in this example, the second power supply voltage Vcc2 is 2 V), that is, when the power is low, the efficiency is higher when the first power supply voltage Vcc1 is lower (in this example, the first power supply voltage Vcc1 is 2 V).

Therefore, as described above, the processing part 101 outputs the signal S2 to the control part 11 on the basis of the signal S1 that represents the power. The control part 11 controls the variable resistor 23 on the basis of the signal S2. The regulator 12 outputs the first power supply voltage Vcc1 to the first amplifier PA1 in a manner that depends on the resistance value of the variable resistor 23. The regulator 12 increases the first power supply voltage Vcc1 as the power increases, while the regulator 12 decreases the first power supply voltage Vcc1 as the power decreases.

Because of this, the power amplifying circuit 1 can improve the efficiency.

Further, no envelope tracking technique is applied to the first power supply voltage Vcc1. Accordingly, for the FET of the first amplifier PA1, the voltage between terminals is suppressed from exceeding the breakdown voltage between terminals, even in the case where the bias voltage (gate voltage) cannot be varied at high speeds. Because of this, the power amplifying circuit 1 can suppress damage to the first amplifier PA1.

As described above, the power amplifying circuit 1 can balance the improvement of the efficiency and the suppression of damage to the first amplifier PA1.

### Second Embodiment

### Configuration

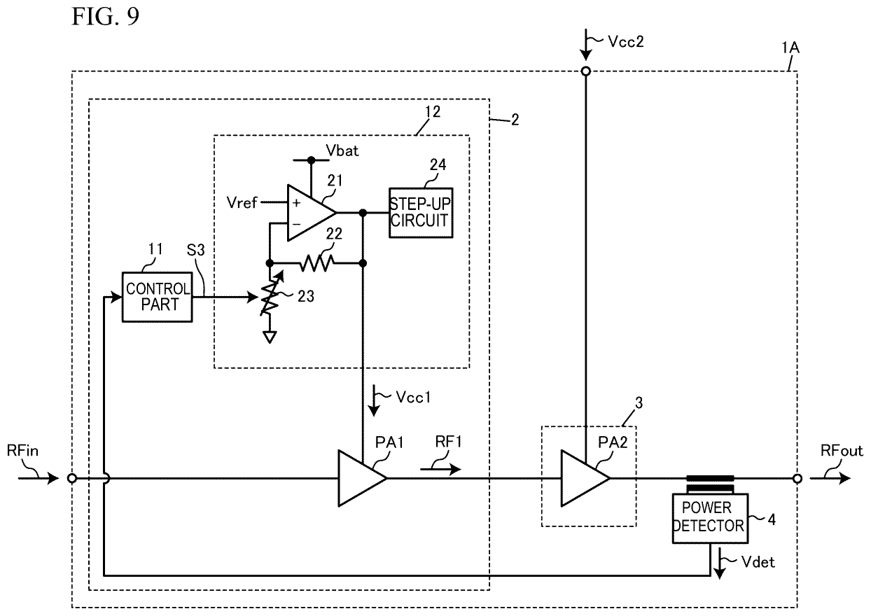

FIG. 9 is a diagram illustrating a configuration of a power amplifying circuit according to the second embodiment.

Compared with the power amplifying circuit 1 (see FIG. 1), a power amplifying circuit 1A further includes a power detector 4. In the second embodiment, the processing part 101 and the memory part 102 (see FIG. 1) are not required.

The power detector 4 detects the output power Pout of the second amplifier PA2 and outputs a voltage Vdet that depends on the output power Pout to the control part 11. The control part 11 controls the variable resistor 23 on the basis of the voltage Vdet.

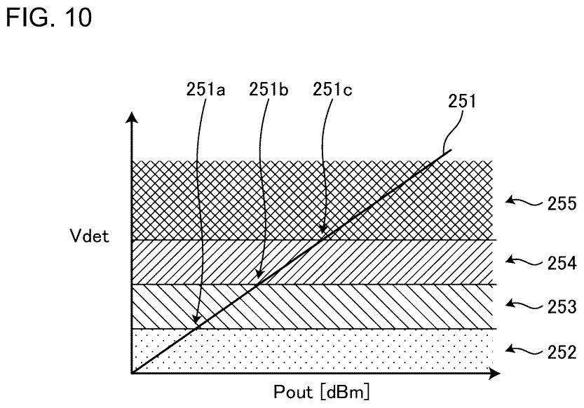

FIG. 10 is a diagram illustrating one example of a detection characteristic of the power detector. In FIG. 10, the horizontal axis represents the output power Pout [dBm], and the vertical axis represents the voltage Vdet [V].

The power detector 4 increases the voltage Vdet as the output power Pout increases. In the example of FIG. 10, the voltage Vdet is directly proportional to the output power Pout. However, the present disclosure is not limited thereto.

The control part 11 controls the resistance value of the variable resistor 23 in such a way that the resistance value of the variable resistor 23 decreases as the output power Pout increases, that is, as the voltage Vdet increases, and as the output power Pout increases, the regulator 12 increases the first power supply voltage Vcc1.

The control part 11 controls the resistance value of the variable resistor 23 in such a way that the resistance value of the variable resistor 23 increases as the output power Pout decreases, that is, as the voltage Vdet decreases, and as the output power Pout decreases, the regulator 12 decreases the first power supply voltage Vcc1.

In the example of FIG. 10, the regulator 12 outputs a constant voltage of 2 V as the first power supply voltage Vcc1 to the first amplifier PA1 in a region 252 where the voltage Vdet is less than that of a point 251a. The regulator 12 outputs a constant voltage of 3 V as the first power supply voltage Vcc1 to the first amplifier PA1 in a region 253 where the voltage Vdet is equal to or greater than that of the point 251a and less than that of a point 251b. The regulator 12 outputs a constant voltage of 4 V as the first power supply voltage Vcc1 to the first amplifier PA1 in a region 254 where the voltage Vdet is equal to or greater than that of the point 251b and less than that of a point 251c. The regulator 12 outputs a constant voltage of 5 V as the first power supply voltage Vcc1 to the first amplifier PA1 in a region 255 where the voltage Vdet is equal to or greater than that of the point 251c.

### Effects

The power detector 4 detects the output power Pout and outputs the voltage Vdet that depends on the output power Pout to the control part 11. The control part 11 controls the variable resistor 23 on the basis of the voltage Vdet. The regulator 12 outputs the first power supply voltage Vcc1 to the first amplifier PA1 in a manner that depends on the resistance value of the variable resistor 23. The regulator 12 increases the first power supply voltage Vcc1 as the output power Pout increases, while the regulator 12 decreases the first power supply voltage Vcc1 as the output power Pout decreases.

Because of this, as is the case with the power amplifying circuit 1, the power amplifying circuit 1A can improve the efficiency.

Further, no envelope tracking technique is applied to the first power supply voltage Vcc1. Accordingly, for the FET of the first amplifier PA1, the voltage between terminals is suppressed from exceeding the breakdown voltage between terminals, even in the case where the bias voltage (gate voltage) cannot be varied at high speeds. Because of this, the power amplifying circuit 1A can suppress damage to the first amplifier PA1.

As described above, the power amplifying circuit 1A can balance the improvement of the efficiency and the suppression of damage to the first amplifier PA1.

### Third Embodiment

### Configuration

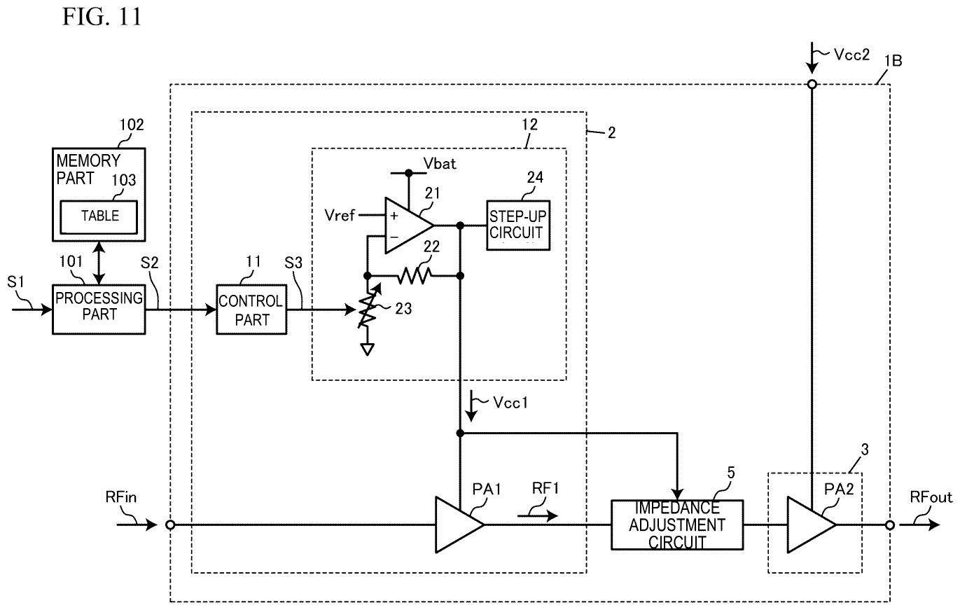

FIG. 11 is a diagram illustrating a configuration of a power amplifying circuit according to the third embodiment.

Compared with the power amplifying circuit 1 (see FIG. 1), a power amplifying circuit 1B further includes an impedance adjustment circuit 5. One end portion of the impedance adjustment circuit 5 is electrically connected to the output terminal of the first amplifier PA1. The other end portion of the impedance adjustment circuit 5 is electrically connected to the input terminal of the second amplifier PA2.

The impedance adjustment circuit 5 may double as an interstage matching circuit between the first amplifier PA1 and the second amplifier PA2.

The impedance value of the impedance adjustment circuit 5 varies in a manner that depends on the first power supply voltage Vcc1. For example, the impedance value of the impedance adjustment circuit 5 decreases as the first power supply voltage Vcc1 increases, while the impedance value of the impedance adjustment circuit 5 increases as the first power supply voltage Vcc1 decreases.

### Effects

The first power supply voltage Vcc1 at which the efficiency of the power amplifying circuit 1B peaks varies in a manner that depends on the load impedance of the first amplifier PA1. In other words, when the first power supply voltage Vcc1 varies, the load impedance of the first amplifier PA1 at which the efficiency peaks also varies.

Therefore, the impedance value of the impedance adjustment circuit 5 varies in a manner that depends on the first power supply voltage Vcc1. For example, the impedance value of the impedance adjustment circuit 5 decreases as the first power supply voltage Vcc1 increases, while the impedance value of the impedance adjustment circuit 5 increases as the first power supply voltage Vcc1 decreases.

Because of this, compared with the power amplifying circuit 1, the power amplifying circuit 1B can further improve the efficiency.

### Fourth Embodiment

### Configuration

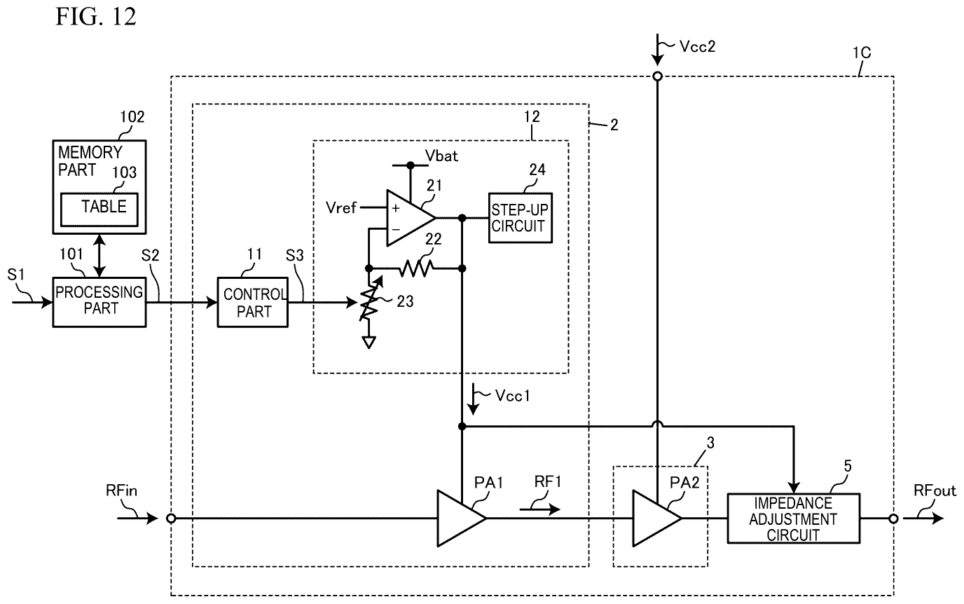

FIG. 12 is a diagram illustrating a configuration of a power amplifying circuit according to the fourth embodiment.

Compared with the power amplifying circuit 1B (see FIG. 11), in a power amplifying circuit 1C, the impedance adjustment circuit 5 is electrically connected to the output terminal of the second amplifier PA2.

### Effects

The first power supply voltage Vcc1 at which the efficiency of the power amplifying circuit 1C peaks varies in a manner that depends on the load impedance of the second amplifier PA2. In other words, when the first power supply voltage Vcc1 varies, the load impedance of the second amplifier PA2 at which the efficiency peaks also varies.

Therefore, the impedance value of the impedance adjustment circuit 5 varies in a manner that depends on the first power supply voltage Vcc1. For example, the impedance value of the impedance adjustment circuit 5 decreases as the first power supply voltage Vcc1 increases, while the impedance value of the impedance adjustment circuit 5 increases as the first power supply voltage Vcc1 decreases.

Because of this, as is the case with the power amplifying circuit 1B, the power amplifying circuit 1C can further improve the efficiency.

### Fifth Embodiment

### Configuration

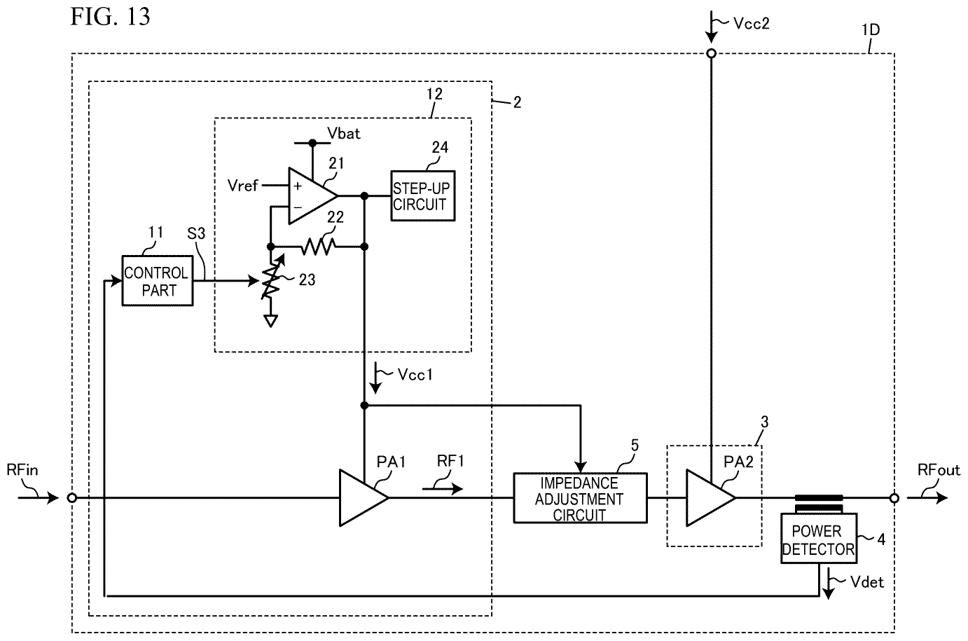

FIG. 13 is a diagram illustrating a configuration of a power amplifying circuit according to the fifth embodiment.

Compared with the power amplifying circuit 1A (see FIG. 9), a power amplifying circuit 1D further includes the impedance adjustment circuit 5. One end portion of the impedance adjustment circuit 5 is electrically connected to the output terminal of the first amplifier PA1. The other end portion of the impedance adjustment circuit 5 is electrically connected to the input terminal of the second amplifier PA2.

Note that although it is not illustrated, the impedance adjustment circuit 5 may be electrically connected to the control part 11.

### Effects

The first power supply voltage Vcc1 at which the efficiency of the power amplifying circuit 1D peaks varies in a manner that depends on the load impedance of the first amplifier PA1. In other words, when the first power supply voltage Vcc1 varies, the load impedance of the first amplifier PA1 at which the efficiency peaks also varies.

Therefore, the impedance value of the impedance adjustment circuit 5 varies in a manner that depends on the first power supply voltage Vcc1. For example, the impedance value of the impedance adjustment circuit 5 decreases as the first power supply voltage Vcc1 increases, while the impedance value of the impedance adjustment circuit 5 increases as the first power supply voltage Vcc1 decreases.

Because of this, compared with the power amplifying circuit 1A, the power amplifying circuit 1D can further improve the efficiency.

### Sixth Embodiment

### Configuration

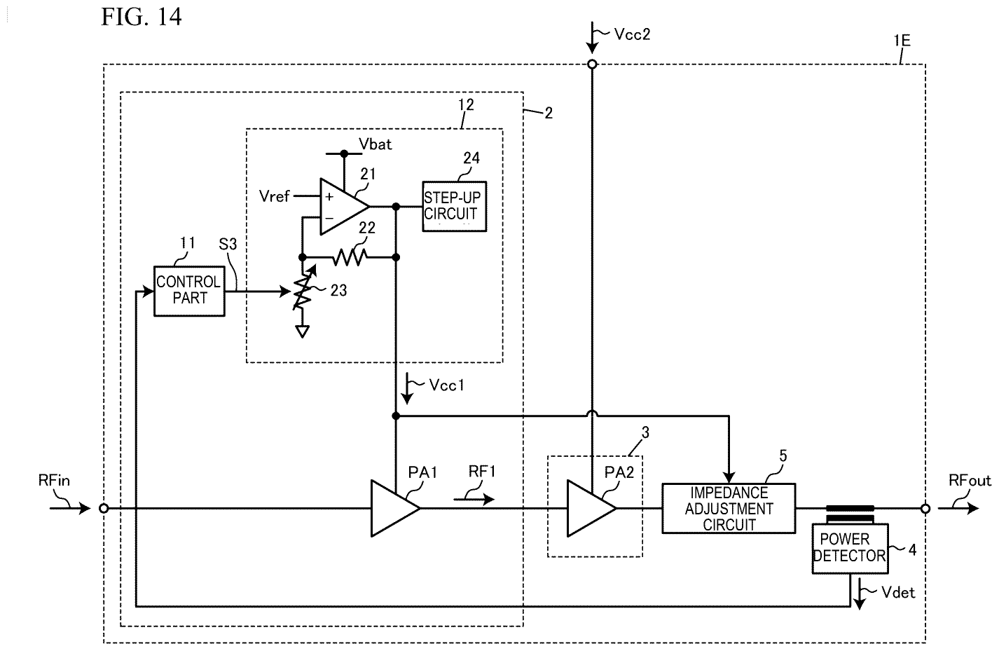

FIG. 14 is a diagram illustrating a configuration of a power amplifying circuit according to the sixth embodiment.

Compared with the power amplifying circuit 1D (see FIG. 13), in a power amplifying circuit 1E, the impedance adjustment circuit 5 is electrically connected to the output terminal of the second amplifier PA2.

Note that although it is not illustrated, the impedance adjustment circuit 5 may be electrically connected to the control part 11.

### Effects

The first power supply voltage Vcc1 at which the efficiency of the power amplifying circuit 1E peaks varies in a manner that depends on the load impedance of the second amplifier PA2. In other words, when the first power supply voltage Vcc1 varies, the load impedance of the second amplifier PA2 at which the efficiency peaks also varies.

The impedance value of the impedance adjustment circuit 5 varies in a manner that depends on the first power supply voltage Vcc1. For example, the impedance value of the impedance adjustment circuit 5 decreases as the first power supply voltage Vcc1 increases, while the impedance value of the impedance adjustment circuit 5 increases as the first power supply voltage Vcc1 decreases.

Because of this, as is the case with the power amplifying circuit 1D, the power amplifying circuit 1E can further improve the efficiency.

### Additional Statement

The impedance adjustment circuit 5 is configured to be electrically connected between the second amplifier PA2 and the power detector 4. However, the present disclosure is not limited thereto. Alternatively, the impedance adjustment circuit 5 may be electrically connected in such a manner as to follow the power detector 4.

### Examples of Configuration of the Present Disclosure

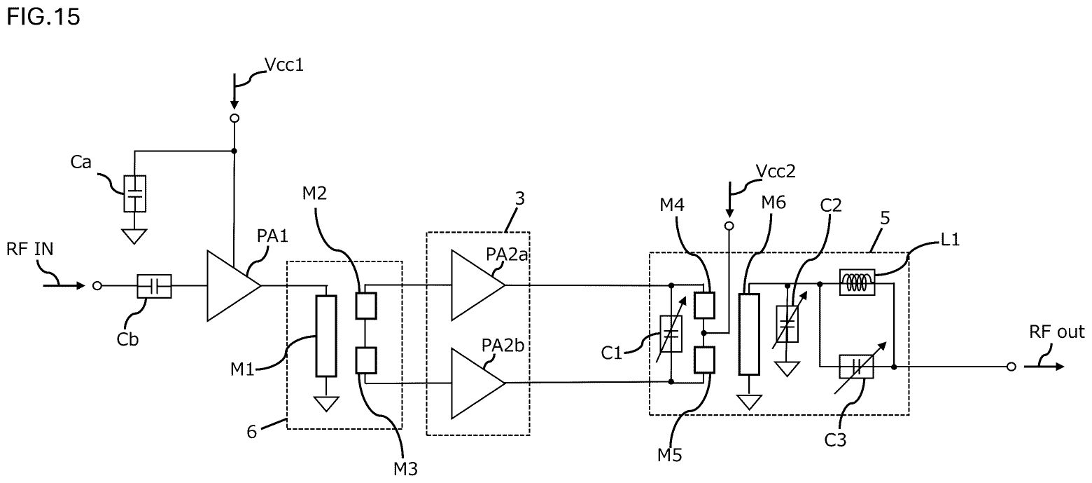

FIG. 15 is a diagram illustrating a configuration of one example of the configuration of the impedance adjustment circuit 5 in the power amplifying circuit according to the fourth embodiment.

In this example, the power amplifier 3 is the differential PA or the Doherty PA comprising power amplifiers PA2a and PA2b.

The impedance adjustment circuit 5 includes variable capacitors C1, C2, C3, inductor L1, and microstrip lines M4, M5, M6 . . . .

The desired impedance is adjusted using three elements C1 to C3. Capacitor C1 can be built into the PA-IC and can be configured as a BiFET or other switch device to adjust the capacitance value (not shown in the figure). Capacitors C2 and C3 can be built into a MOS-IC such as a BSSW to adjust the constant (not shown in the figure). The impedance adjustment circuit 5 is not limited to the configuration shown in the example, and the entire impedance adjustment circuit 5 can be arranged in the PA-IC.

Additionally, FIG. 15 includes matching network 6. For example, the matching network 6 can comprise of microstrip lines M1, M2, M3. In other embodiments the matching network can comprise transformer, adjustable resistance elements, capacitors, inductors, and the like. Further, a capacitor Ca can be connected between the first power supply voltage Vcc1 line and ground. Capacitor Cb can also be connected between RFin and the power amplifier PA1. Capacitors Ca and Cb can be configured as matching circuits or filters. Capacitors Ca and Cb can be also be adjustable capacitors, and be built into the PA-IC or MOS-IC.

The present disclosure can also have the following configurations.

(1)

A power amplifying circuit comprising:
a first amplifier that includes a field effect transistor as an amplifying element, amplifies a first radio frequency signal, and outputs a second radio frequency signal;
a second amplifier that includes a bipolar transistor as an amplifying element, amplifies the second radio frequency signal, and outputs a third radio frequency signal;
a control part that outputs a control signal, the control signal controlling a first power supply voltage to be supplied to the first amplifier; and
a regulator that outputs the first power supply voltage to the first amplifier, the first power supply voltage being a voltage that depends on the control signal, wherein
a second power supply voltage to be supplied to the second amplifier is an envelope tracking voltage.
   (2)

The power amplifying circuit according to (1) above, wherein
the control part controls the first power supply voltage in a manner that depends on power.
   (3)

The power amplifying circuit according to (1) above, further comprising:
a power detector that detects output power of the second amplifier, wherein
the control part controls the first power supply voltage in a manner that depends on the output power.
   (4)

The power amplifying circuit according to any one of (1) to (3) above, wherein
the regulator includes
   an operational amplifier that receives a reference voltage from a non-inverting input terminal thereof and outputs the first power supply voltage from an output terminal thereof,
   a resistor that is electrically connected to the output terminal of the operational amplifier at one end portion thereof and electrically connected to an inverting input terminal of the operational amplifier at another end portion thereof, and
   a variable resistor that is electrically connected to the inverting input terminal of the operational amplifier at one end portion thereof and electrically connected to a reference potential at another end portion thereof, a resistance value of the variable resistor varying in a manner that depends on the control signal.
      (5)

The power amplifying circuit according to any one of (1) to (4) above, further comprising:
an impedance adjustment circuit that adjusts load impedance of the first amplifier or the second amplifier in a manner that depends on the first power supply voltage.

Note that the embodiments described above are provided to facilitate understanding of the present disclosure and are not to be construed as limiting the present disclosure. The present disclosure can be modified or improved without necessarily departing from its spirit, and the present disclosure also includes equivalents thereof.

What is claimed is:

1. A power amplifying circuit comprising:
a first amplifier that comprises a field effect transistor configured to amplify a first radio frequency signal and output a second radio frequency signal;
a second amplifier that comprises a bipolar transistor configured to amplify the second radio frequency signal and output a third radio frequency signal;
a control part configured to output a control signal;
a regulator configured to that output the first power supply voltage to the first amplifier, the first power supply voltage is a voltage based on the control signal; and
a second power supply voltage supplied to the second amplifier, the second power supply voltage is configured to be an envelope tracking voltage.

2. The power amplifying circuit according to claim 1, wherein the control part is configured to control the first power supply voltage based on power.

3. The power amplifying circuit according to claim 1, further comprising:
a power detector configured to detect output power of the second amplifier,
wherein the control part is configured to control the first power supply voltage based on the output power of the second amplifier.

4. The power amplifying circuit according to claim 1, wherein the regulator comprises:
an operational amplifier configured to receive a reference voltage via a non-inverting input terminal and output the first power supply voltage from an output terminal,
a resistor with a first end electrically connected to the output terminal and a second end electrically connected to an inverting input terminal of the operational amplifier, and
a variable resistor with a first end electrically connected to the inverting input terminal and a second end electrically connected to a reference potential, a resistance value of the variable resistor is configured to vary based on the control signal.

5. The power amplifying circuit according to claim 1, further comprising:
an impedance adjustment circuit configured to adjust the load impedance of the first amplifier or the second amplifier based on the first power supply voltage.

6. The power amplifying circuit according to claim 4,
wherein the variable resistor comprises a plurality of switches and resistors in parallel, and
wherein in case where the output power of the amplifying circuit increases, the control part is configured to decrease the resistance value of the variable resistor.

7. The power amplifying circuit according to claim 4, further comprising:
a step-up circuit electrically connected to the output terminal,
wherein the step-up circuit is configured to operate based the first power supply voltage.

8. A cellular communication device comprising:
a processing part configured to output a control signal to the power amplifying circuit according to claim 1;
a control part of the cellular communication device configured to output an output signal representative of the output power of the cellular communication device to the processing part,
wherein the cellular communication device is configured to operate in a plurality of power modes based on the output signal representative of the output power of the cellular communication device.
